(19) United States
(12) Patent Application Publication
(10) Pub. No.: US 2025/0233391 A1
(43) Pub. Date: Jul. 17, 2025

(54) MULTI-JUNCTION LASER-DIODE MODULES CONFIGURED FOR FIBER-COUPLING

(71) Applicant: Electro-Optics Technology, Incorporated, Traverse City, MI (US)

(72) Inventor: David G. SCERBAK, Traverse City, MI (US)

(73) Assignee: Electro-Optics Technology, Incorporated, Traverse City, MI (US)

(21) Appl. No.: 19/012,288

(22) Filed: Jan. 7, 2025

Related U.S. Application Data
(60) Provisional application No. 63/621,299, filed on Jan. 16, 2024.

(51) Int. Cl. H01S 5/40; G02B 27/09; G02B 27/14; H01S 5/00; H01S 5/02253

(52) U.S. Cl. CPC H01S 5/4043; G02B 27/0922; G02B 27/14; H01S 5/0071; H01S 5/02253; H01S 5/4012; H01S 5/4081

(57) ABSTRACT

A multi-junction laser-diode module includes (a) a multi-junction laser diode having a plurality of laser junctions stacked in a vertical dimension parallel to the fast-axes of the laser beams emitted by the laser junctions, (b) a fast-axis cylindrical lens collimating each laser beam in the fast axis, whereby the laser beams emerge from the fast-axis cylindrical lens with mutually nonparallel propagation directions, (c) a transmissive beam-deflecting element that deflects the laser beams in the fast-axis dimension after the fast-axis cylindrical lens to make their propagation directions parallel, and (d) a slow-axis cylindrical lens configured to collimate each laser beam in the slow axis. The transmissive beam-deflecting element corrects for the propagation-direction discrepancy between the laser beams, in the fast-axis dimension, caused by fast-axis collimation. The multi-junction laser-diode module can thereby produce a laser beam bundle suitable for high-brightness fiber-coupling.

### CROSS-REFERENCE TO RELATED APPLICATION

This application claims the benefit of U.S. Provisional Application No. 63/621,299, filed Jan. 16, 2024, the entire contents of which is incorporated herein by reference.

### TECHNICAL FIELD OF THE INVENTION

The present invention relates in general to high-brightness fiber-coupled diode-laser systems. The present invention relates in particular to coupling multiple laser beams, generated by a multi-junction laser diode, into an optical fiber.

### DISCUSSION OF BACKGROUND ART

A standard laser diode has a single laser junction between electron-donor and electron-acceptor doped regions of a semiconductor material, such as gallium arsenide. One end of this relatively thin laser junction region has a reflective coating, and the opposite end has a partially reflective coating. These two reflective coatings form a resonator for the laser junction. When the laser junction is forward biased, electron-hole recombination leads to generation of light. The light is amplified by stimulated emission in the resonator to produce a laser beam emitted through the partially reflective coating.

Single-junction laser diodes are routinely fiber-coupled. It is also possible to create a high-brightness fiber source by spatially combining the beams from several single-junction laser diodes before coupling the combined beam into an optical fiber. In a typical design, multiple single-junction laser diodes are arranged side-by-side. The laser beams are collimated and deflected onto a common path to form a vertical stack of parallel-propagating, collimated laser beams. A focusing lens couples this stack of laser beams into an optical fiber.

Owing to diffraction and the geometry of the laser junctions, each laser beam emerges from its single-junction laser diode highly asymmetric with a small size and rapid divergence in one transverse dimension, termed the “fast axis”, and a larger size and slower divergence in the orthogonal transverse dimension, termed the “slow axis”. Therefore, for each laser beam, fast-axis collimation is performed with a cylindrical lens positioned very close to the single-junction laser diode, and slow-axis collimation is performed with another, more distant cylindrical lens.

In some laser applications, power conversion efficiency is important. The power conversion efficiency of a laser is the ratio of the output laser power to the electrical input power required for laser operation. The power conversion efficiency of a single-junction laser diode is usually much higher than that of lasers using non-semiconductor gain media, e.g., gas lasers, solid-state lasers, and fiber lasers. A single-junction laser diode may have a power conversion efficiency as high as, or higher than, 60%. The high efficiency of fiber-coupled single-junction laser diodes in conjunction with the high-brightness achievable when coupling the output of several single-junction laser diodes into a single optical fiber has enabled rapid advances in the development and use of efficient high-brightness fiber-coupled laser sources. The output laser beam from such high-brightness fiber sources may be used to perform industrial materials-processing tasks, or used to pump other solid-state lasers, including fiber lasers. For example, many fiber lasers are pumped by laser light coupled into the cladding of the gain fiber, and the performance of such fiber lasers benefits from the cladding being relatively thin. The cladding-coupled pump laser power is maximized when the pump laser beam(s) have high brightness.

A multi-junction laser diode has a stack of several laser junctions formed in the same block of semiconductor material. Between each pair of adjacent laser junctions is a tunnel junction. It is possible in some cases to form a common laser resonator around the full stack of laser junctions of a multi-junction laser diode, such that the multi-junction laser diode emits a single laser beam. However, in designs intended for high-power continuous-wave operation, heat sinking constraints usually necessitate forming a separate laser resonator around each individual laser junction. In such designs, the multi-junction laser diode emits a separate laser beam from each laser junction. In these designs, the multi-junction laser diode is said to contain multiple emitters. These emitters are typically not coherent with respect to each other. The fast axes of the emitted laser beams are parallel to the stacking direction.

### SUMMARY OF THE INVENTION

Multi-junction laser diodes are an appealing choice for many applications, including high-brightness fiber sources and other fiber-coupled laser systems. These multi-junction laser diodes contain multiple emitters in a small package that requires less electronic and mechanical hardware than multiple single-junction laser diodes. Additionally, multi-junction laser diodes have demonstrated even greater power conversion efficiency than single-junction laser diodes. However, fiber-coupling the output of a multi-junction laser diode having multiple emitters presents a unique challenge: Fast-axis collimation of the multiple emitted laser beams introduces a propagation-direction discrepancy between the laser beams. Unless mitigated, this propagation-direction discrepancy precludes coupling of the multiple laser beams into a single optical fiber with high brightness.

The reasons for the propagation-direction discrepancy are as follows. The relatively rapid beam divergence in the fast axis of each laser beam necessitates performing fast-axis collimation close to the output of the multi-junction laser diode. Concurrently, the short distance between adjacent emitters makes it impractical to implement a separate fast-axis collimation lens for each laser beam. All laser beams are therefore fast-axis collimated by the same, single cylindrical lens. Each laser beam emerges from this cylindrical lens with a different propagation direction.

Disclosed herein are multi-junction laser diode modules that utilize a transmissive beam-deflecting element to correct for the propagation-direction discrepancy. Each of these laser modules is thereby capable of producing a laser beam bundle suitable for high-brightness fiber-coupling.

In one aspect of the invention, a multi-junction laser-diode module includes a multi-junction laser diode having a plurality of laser junctions stacked in a vertical dimension. The plurality of laser junctions are configured to emit a respective plurality of laser beams offset from each other in the vertical dimension. Each laser beam diverges more rapidly in a fast axis than in an orthogonal slow axis. The fast axis of each laser beam is parallel to the vertical dimension where the laser beam emerges from the multi-junction laser diode. The multi-junction laser-diode module further includes a fast-axis cylindrical lens configured to collimate each laser beam in the fast axis, whereby the laser beams emerge from the fast-axis cylindrical lens with mutually nonparallel propagation directions. The multi-junction laser-diode module also includes a slow-axis cylindrical lens configured to collimate each laser beam in the slow axis. Additionally, the multi-junction laser-diode module includes a transmissive beam-deflecting element disposed after the fast-axis cylindrical lens. The transmissive beam-deflecting element is configured to deflect all or all but one of the laser beams in a first plane, parallel to the fast axes of the laser beams, such that the laser beams emerge from the transmissive beam-deflecting element with mutually parallel propagation directions.

### BRIEF DESCRIPTION OF THE DRAWINGS

The accompanying drawings, which are incorporated in and constitute a part of the specification, schematically illustrate preferred embodiments of the present invention, and together with the general description given above and the detailed description of the preferred embodiments given below, serve to explain principles of the present invention.

FIGS. 1A and 1B illustrate a dual-junction laser-diode module configured for fiber coupling and capable of coupling a pair of laser beams, emitted by a dual-junction laser diode, into an optical fiber with high brightness, according to an embodiment. The dual-junction laser-diode module includes a prism that corrects for a propagation-direction discrepancy between the two laser beams. This propagation-direction discrepancy is introduced by the process of collimating the laser beams in their fast axis.

FIG. 2 is a close-up of a portion of FIG. 1A, providing a more detailed view of the dual-junction laser diode and an associated fast-axis collimation lens.

FIG. 3 shows the prism of the dual-junction laser-diode module of FIGS. 1A and 1B in further detail.

FIG. 4 shows an exemplary transverse profile of the laser beam bundle, emitted by the dual-junction laser diode of the dual-junction laser-diode module of FIGS. 1A and 1B, on the input face of an optical fiber.

FIG. 5 shows, for comparison, a fiber-coupled dual-junction laser-diode module that is not corrected for the propagation-direction-discrepancy introduced by fast-axis collimation.

FIG. 6 shows an exemplary transverse profile of the laser beam bundle, emitted by the dual-junction laser diode of the dual-junction laser-diode module of FIG. 5, on the input face of an optical fiber positioned at the focal plane of a focusing lens.

FIG. 7 shows an exemplary transverse profile of the laser beam bundle, emitted by the dual-junction laser diode of the dual-junction laser-diode module of FIG. 5, on the input face of an optical fiber positioned behind the focal plane at a location of optimal spatial overlap between the two laser beams of the of laser beam bundle.

FIG. 8 illustrates a triple-junction laser-diode module configured for fiber coupling and capable of coupling three laser beams, emitted by a triple-junction laser diode, into an optical fiber with high brightness, according to an embodiment. This triple-junction laser-diode module is an extension of the dual-junction laser-diode module of FIGS. 1A and 1B to a triple-junction laser diode emitting three laser beams.

FIG. 9 shows a prism of the triple-junction laser-diode module of FIG. 8 in further detail. This prism corrects for a propagation-direction discrepancy between the three laser beams, introduced by fast-axis collimation.

FIG. 10 illustrates one prism that may replace the prism of the dual-junction laser-diode module of FIGS. 1A and 1B, according to an embodiment.

FIG. 11 illustrates another prism that may replace the prism of the dual-junction laser-diode module of FIGS. 1A and 1B, according to an embodiment

FIG. 12 illustrates a dual-junction laser-diode apparatus that includes multiple dual-junction laser-diode modules and combines the output thereof, according to an embodiment. The dual-junction laser-diode modules are arranged side-by-side, and each is corrected for propagation-direction discrepancies introduced by fast-axis collimation.

FIG. 13 is a front view of the output faces of the dual-junction laser diodes of the dual-junction laser-diode apparatus of FIG. 12.

FIGS. 14A-D are a series of exemplary laser beam profiles taken at different locations in the dual-junction laser-diode apparatus of FIG. 12.

FIG. 15 illustrates another dual-junction laser-diode apparatus that includes multiple dual-junction laser-diode modules and combines the output thereof, according to an embodiment. The dual-junction laser-diode modules are arranged above each other, and each is corrected for propagation-direction discrepancies introduced by fast-axis collimation.

### DETAILED DESCRIPTION OF THE INVENTION

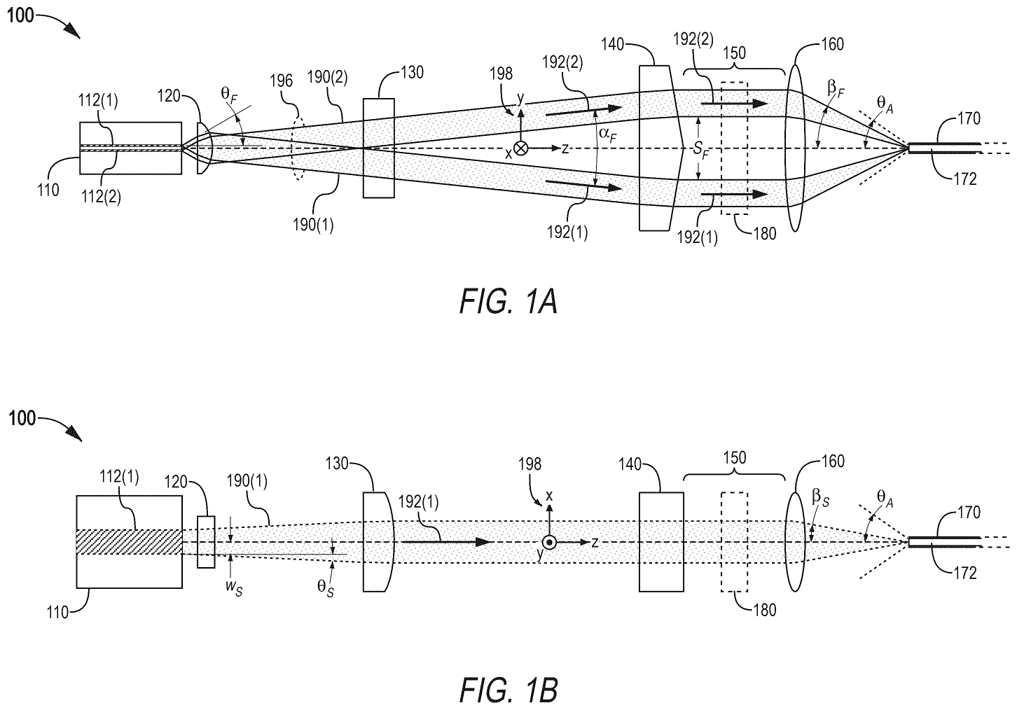

Referring now to the drawings, wherein like components are designated by like numerals, FIGS. 1A and 1B are orthogonal cross-sectional views of one dual-junction laser-diode module 100 configured for fiber coupling and capable of coupling a pair of laser beams, emitted by a dual-junction laser diode, into an optical fiber with high brightness. The cross section of FIG. 1A is in the yz-plane of a cartesian coordinate system 198, whereas the cross section of FIG. 1B is in the xz-plane of coordinate system 198. Hereinafter, any mention of x-, y-, and z-axes, dimensions, and associated planes refers to coordinate system 198.

Module 100 includes a dual-junction laser diode 110 having two laser junctions 112 emitting two laser beams 190, respectively. The two junctions 112 are labeled 112(1) and 112(2) in FIGS. 1A and 1B. Similarly, the two beams 190 are labeled 190(1) and 190(2). Module 100 further includes two cylindrical lenses: a fast-axis lens 120 that collimates each beam 190 in its fast axis, and a slow-axis lens 130 that collimates each beam 190 in its slow axis. Each of lenses 120 and 130 may be aspheric. Module 100 also includes a prism 140 that corrects for a discrepancy between the propagation directions of beams 190. This correction by prism 140 serves to create a situation where beams 190 are both collimated and mutually parallel, which is advantageous for fiber-coupling with high brightness.

The brightness of a laser beam is qualitatively equivalent to the radiance of the laser beam and serves as an indicator of the laser intensity achievable by focusing the laser beam. The brightness of laser light depends on the power of the laser light as well as its beam quality. One measure of beam quality is the beam parameter product BPP=w₀θ₀, where w₀ and θ₀ are the beam radius (half-width) at the waist of the laser beam and the beam divergence half-angle at the 1/e² intensity levels. Brightness is then quantifiable as laser radiance L=P/(π²BPP²). A diffraction-limited laser beam coincides with the lowest possible value for the beam parameter product, namely BPPₘᵢₙ=λ/π, wherein λ is the wavelength of the laser beam. The beam parameter product will be larger for a non-diffraction-limited, or multi-mode, laser beam. As will be discussed in further detail below, the inclusion of prism 140 in module 100 makes it possible to achieve a relatively high brightness and low combined beam parameter product of beams 190.

In an exemplary scenario, shown in FIGS. 1A and 1B, a focusing lens 160 directs both beams 190 towards the input face and core of an optical fiber 170 and thereby couples beams 190 into fiber 170 with high brightness. Although focusing lens 160 is depicted as a singlet lens, focusing lens 160 may include several optical elements that cooperate to focus beams 190. For example, focusing lens 160 may include two or more lenses in contact or not in contact with each other. Certain embodiments of module 100 include focusing lens 160. These embodiments may also include optical fiber 170 or a fiber port configured to receive optical fiber 170.

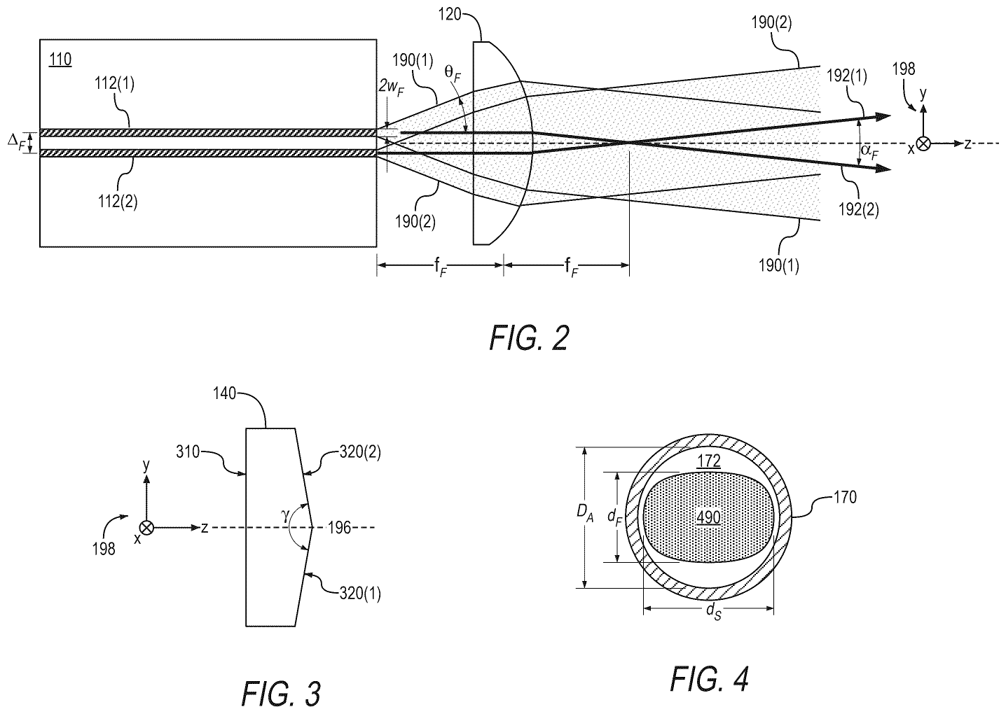

FIG. 2 is a close-up of a portion of FIG. 1A, providing a more detailed view of dual-junction laser diode 110 and fast-axis lens 120. The propagation of beams 190 in module 100 is best understood by viewing FIGS. 1A, 1B, and 2 together. As shown in FIG. 2, junctions 112 are arranged in a stack within diode 110. Junctions 112 are stacked on each other, that is, offset from each other by a non-zero offset Δ_{F} in a vertical dimension of the stack. Offset Δ_{F} is typically less than 10 micrometers (μm), for example between 3 and 6 μm. (Herein, the terms “horizontal” and “vertical” merely denote two orthogonal dimensions and do not imply a particular orientation with respect to the gravitational force.) The vertical dimension is parallel to the y-axis. In most embodiments, there is no offset or only a negligible offset between junctions 112 in dimensions orthogonal to the vertical dimension of the stack. For simplicity and without loss of generality, the following discussion assumes that there is no offset, or only a negligible offset, between junctions 112 in dimensions orthogonal to the vertical dimension of the stack.

When emerging from diode 110, laser beams 190 propagate parallel to each other along the z-axis with offset Δ_{F} therebetween. The fast axis of each laser beam 190 is parallel to the y-axis and the slow axis of each laser beam 190 is parallel to the x-axis. The z-axis coincides with a central propagation axis of the laser beam bundle 196 formed by beams 190. In the depicted embodiment, the central propagation axis of beam bundle 196 is straight. Without departing from the scope hereof, the central propagation axis of beam bundle 196 may be folded, and/or rotated in one or more places. Such folding/rotation may be achieved by the inclusion of additional optical elements (not depicted). If the central propagation axis of beam bundle 196 is folded or rotated, coordinate system 198 is assumed to follow the propagation of beams 190 such that the z-axis continues to coincide with the central propagation axis of beam bundle 196. In such cases, FIGS. 1A and 1B represent unfolded/unrotated views of module 100 along the central propagation axis of beam bundle 196.

FIG. 1A and FIG. 2 show the propagation behavior of beams 190 in a fast-axis plane containing the beam axis and fast axis of each beam 190. This fast-axis plane coincides with the yz-plane. To illustrate the slow-axis propagation behavior, FIG. 1B shows the projection of junction 112(1) and beam 190(1) onto the xz-plane. The slow-axis propagation behavior of beam 190(2) is similar to that of beam 190(1). FIGS. 1A and 1B schematically depict each beam 190 as the 1/e² envelope of its transverse intensity distribution.

At the output of diode 110, the fast-axis dimension of each laser beam 190 is characterized by a relatively small 1/e² waist w_{F} and a relatively large fast-axis divergence angle θ_{F} (see FIGS. 1A and 2). Conversely, the slow-axis dimension of each laser beam 190 is, at the output of diode 110, characterized by a relatively large 1/e² waist w_{S} and a relatively small fast-axis divergence angle θ_{S} (see FIG. 1B). In a typical implementation, each beam 190 is substantially diffraction-limited in the fast-axis dimension while being multi-modal in the slow-axis dimension. Slow-axis waist w_{S} may be at least ten times fast-axis waist w_{F} or even more than 100 times fast-axis waist w_{F}, and fast-axis divergence angle θ_{F} may be at least three times slow-axis divergence angle θ_{S}. In one example, slow-axis waist w_{S} is at least 50 μm, e.g., between 50 and 175 μm, fast-axis waist w_{F} is in the range between 0.6 and 1.5 μm, fast-axis divergence angle θ_{F} is in the range between 20 and 50 degrees, and slow-axis divergence angle θ_{S} is in the range between 2 and 15 degrees.

As a consequence of the relatively rapid fast-axis divergence of beams 190, fast-axis lens 120 is positioned close to diode 110, whereas slow-axis lens 130 is positioned further away. As best seen in FIG. 2, beams 190 are incident on fast-axis lens 120 with parallel propagation directions 192, labeled 192(1) and 192(2) in FIG. 2. Offset Δ_{F} between the respective optical axes of beams 190 is typically too small to allow for separate fast-axis collimation of beams 190(1) and 190(2) using two separate cylindrical lenses. Therefore, both beams 190 are collimated by just one fast-axis lens 120. Due to offset Δ_{F} between beams 190, propagation directions 192 are not parallel when beams 190 emerge from fast-axis lens 120. Instead, propagation directions 192 deviate from each other by a non-zero angle α_{F} in the yz-plane. Angle α_{F} depends on the focal length f_{F} of fast-axis lens 120 and offset Δ_{F} between junctions 112.

In the scenario depicted in FIG. 2, fast-axis lens 120 is positioned one focal length away from diode 110 to collimate each beam 190 in the fast-axis dimension, and beams 190 cross each other on the output side of fast-axis lens 120 at a distance of one focal length away from fast-axis lens 120. For simplicity, this scenario assumes that fast-axis lens 120 can be treated as a thin lens. Beyond the location where beams 190 cross each other, propagation directions 192 are mutually divergent and the offset between beams 190 grows. Focal length f_{F} may be less than approximately one millimeter (mm), e.g., in the range between 0.2 and 0.6 mm. Angle α_{F} may exceed 2.5 milliradians (mrad). In one example, angle α_{F} is in the range between 2.5 and 25 mrad.

After fast-axis collimation by fast-axis lens 120, the fast-axis Rayleigh range of each beam 190 may exceed focal length f_{F} by at least a factor of 10. Since each beam 190 may be nearly diffraction-limited in its fast-axis dimension, the fast-axis Rayleigh range of each beam 190 may exceed focal length f_{F} by as much as a factor of 100 or 1000 or even more. Considering the slow-axis dimension for comparison, where each beam 190 may be multi-modal, slow-axis collimation of each beam 190 by slow-axis lens 130 (see FIG. 1B) may result in each beam 190 having a slow-axis Rayleigh range that is more comparable to the focal length f_{S} of slow-axis lens 130. In one example, the slow-axis Rayleigh range of each beam 190, as collimated by slow-axis lens 130, may be at least 0.5 f_{S}, e.g., between 0.5 f_{S} and 10 f_{S}.

Referring again to FIGS. 1A and 1B, prism 140 serves to correct for the propagation-direction discrepancy of beams 190. Prism 140 is positioned more than focal length f_{F} from fast-axis lens 120, at a location where beams 190 are offset from each other in the yx-plane. Preferably, prism 140 is positioned at a location where beams 190 are substantially separated from each other. At this location, it is possible to steer beams 190 independently of each other. Prism 140 deflects propagation directions 192 toward each other, such that beams 190 emerge from prism 140 with parallel propagation directions 192. Beams 190 may therefore be brought to a common focus with a lens as discussed further below. In one example, prism 140 is positioned at a location where there is no overlap between the individual fast-axis 1/e² transverse intensity distributions of beams 190. For clarity, FIG. 1A depicts a sizeable separation distance S_{F} between beams 190 and in section 150. In practical implementations, separation distance S_{F} may be smaller than depicted. In one example, prism 140 is positioned such that separation distance Sp is in the range between zero and twice the fast-axis 1/e² half-width of individual beams 190.

FIG. 3 shows prism 140 in further detail. Prism 140 includes a planar input facet 310 and two planar output facets 320 (indicated in FIG. 3 as output facets 320(1) and 320(2)). Beam 190(1) passes through input facet 310 and output facet 320(1), and beam 190(2) passes through input facet 310 and output facet 320(2). Output facets 320 are not parallel to each other. The interior angle γ between output facets 320 is less than 180 degrees. The size of interior angle γ depends on angle α_{F} induced by fast-axis lens 120 and the refractive index of prism 140. Angle γ is typically obtuse.

In the depicted embodiment, input facet 310 is orthogonal to the z-axis and each output facet 320 is at the same oblique angle to the z-axis. In this embodiment, beams 190(1) and 190(2) are deflected in the positive and negative y-axis directions, respectively, by the same amount. Prism 140 may be symmetric with respect to reflection in the xz-plane. While output facets 320 are directly connected to each other in the depicted embodiment of prism 140, an alternative embodiment of prism 140 may include an intervening surface portion, e.g., another planar facet or a rounded corner, between output facets 320 in a region not intersected by beams 190.

Prism 140 may be monolithic, for example made of a single piece of glass. Alternatively, prisms 140 may be made of two parts: one part that forms output facet 320(1) and the portion of input facet 310 intersected by beam 190(1), and another part that forms output facet 320(2) and the portion of input facet 310 intersected by beam 190(2). These two parts may be bonded to each other before installation in module 100 or installed separately. However, monolithic embodiments of prism 140 may be preferred for several reasons, including simpler installation and alignment. Additionally, a monolithic prism 140 may minimize any optically-unusable gap between output facets 320, thus allowing for a small separation between beams 190 in prism 140.

In certain embodiments of module 100, discussed further below in relation to fiber coupling, it is advantageous that separation distance Sp (see FIG. 1A) in section 150 is less than twice the fast-axis 1/e² half-width of individual beams 190. Some scenarios may benefit from separation distance Sp being as small as possible, for example zero or less than 20% of the fast-axis 1/e² half-width of individual beams 190. Since interior angle γ between output facets 320 is less than 180 degrees, it is possible to manufacture output facets 320 with high optical quality and a minimal optically-unusable gap therebetween. In one example, any optically-unusable gap between output facets 320 is less than 20 μm.

Although not shown, prism 140 may be implemented in module 100 with the opposite orientation, such that facet 310 is on the output side of prism 140 and facets 320(1) and 320(2) are on the input side of prism 140.

Referring again to FIGS. 1A and 1B, prism 140 may be positioned after slow-axis lens 130, as shown, or before slow-axis lens 130. Whether prism 140 is best positioned before or after slow-axis lens 130 depends on several parameters, including angle α_{F} induced by fast-axis lens 120, slow-axis divergence angle θ_{S} at the output of diode 110, and a desired aspect ratio of the transverse profile of beams 190. Regardless of the order in which prism 140 and slow-axis lens 130 are arranged along the z-axis, prism 140, fast-axis lens 120, and slow-axis lens 130 cooperate to create a section 150 in module 100 where beams 190 are fully collimated (i.e., collimated in both fast and slow axes) and parallel to each other. Section 150 enables fiber-coupling of beams 190 with a high brightness of beam bundle 196 formed by beams 190.

In embodiments of module 100 including focusing lens 160 and optical fiber 170, focusing lens 160 focuses beam bundle 196 on an input face of optical fiber 170. Optical fiber 170 has a core 172. In the depicted embodiment of optical fiber 170, core 172 has a circular cross section, the acceptance aperture of optical fiber 170 has a diameter D_{A} (indicated in FIG. 4), and acceptance angle θ_{A} of optical fiber 170 is rotationally symmetric about the longitudinal axis of optical fiber 170. The depicted example of module 100 is configured such that beam bundle 196 is incident on optical fiber 170 within both the acceptance aperture and acceptance angle of optical fiber 170. Beam bundle 196 is thereby coupled into optical fiber 170.

Between focusing lens 160 and optical fiber 170, the combined 1/e² transverse intensity distribution of bundle 196 is characterized by a fast-axis convergence angle β_{F} and a slow-axis convergence angle β_{S}. Focusing lens 160 may have the same optical power in both the x- and y-dimensions. For example, focusing lens 160 may be rotationally symmetric about the z-axis. The size of fast-axis convergence angle β_{F} depends on several parameters. One of these parameters is the separation between beams 190 when incident on focusing lens 160 (see separation distance S_{F} in FIG. 1A). For a fixed size of collimated beams 190, fast-axis convergence angle β_{F} is an increasing function of this beam separation. Thus, depending on the size of acceptance angle θ_{A} of optical fiber 170, it may be beneficial to configure module 100 with a relatively small beam separation distance S_{F}. In one example S_{F} is zero. Advantageously, as discussed above, prism 140 can be manufactured with a minimal optically-unusable gap between output facets 320, as required when separation distance S_{F} is small.

FIG. 4 shows one exemplary transverse profile 490 of beam bundle 196 on the input face of optical fiber 170 when beam bundle 196 is focused by focusing lens 160, as shown in FIGS. 1A and 1B. Transverse profile 490 is the 1/e² envelope of the transverse intensity distribution of beam bundle 196. Transverse profile 490 does not show two separate beams 190 but rather mimics the transverse profile of a single laser beam. Transverse profile 490 has a fast-axis width d_{F} and a slow-axis width d_{S}. Depending on various parameters of module 100, slow-axis width d_{S} may be significantly greater than fast-axis width d_{F}, as depicted. Referring to FIG. 4 and FIG. 1A in combination, the beam parameter product of bundle 196 is ½ d_{F}β_{F} in the y-dimension and ½ d_{S}β_{S} in the x-dimension.

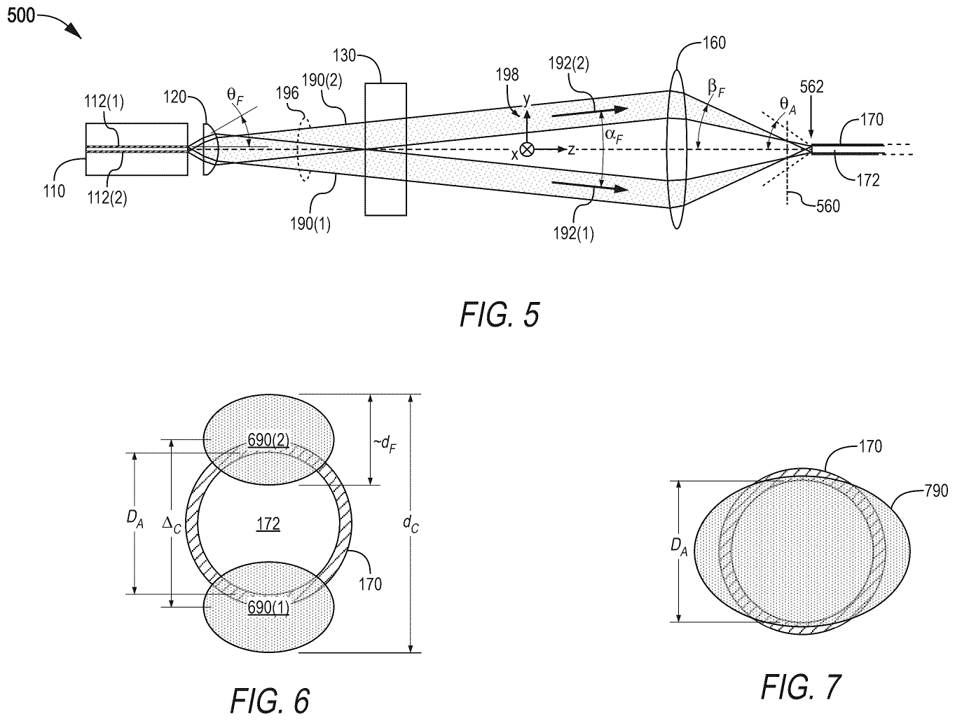

FIG. 5 shows, for comparison, a fiber-coupled dual-junction laser-diode module 500 that is not corrected for the propagation-direction-discrepancy introduced by fast-axis collimation. Module 500 is a modification of module 100 that omits prism 140. Module 500 includes focusing lens 160 and optical fiber 170. FIG. 5 shows module 500 in a view similar to that used for module 100 in FIG. 1A. Due to the absence of prism 140 in module 500, beams 190 remain mutually-nonparallel after fast-axis collimation by fast-axis lens 120. As discussed in further detail below, this propagation-direction discrepancy between beams 190 results in beams 190 being (a) transversely offset from each other at the focal plane of focusing lens 160 and (b) out of focus at the location of optimal transverse overlap between beams 190. This property of beam bundle 196 in module 500 precludes fiber-coupling with high brightness.

In module 500, focusing lens 160 focuses each beam 190 to a respective waist at the focal plane 560 of focusing lens 160. However, because of the mutually-diverging propagations directions 192 of beams 190 as incident on focusing lens 160, focusing lens 160 does not focus both beams 190 of beam bundle 196 to the same location on focal plane 560. Instead, fast-axis lens 120 and focusing lens 160 form an imaging system in the yz-plane that images the output of diode 110 onto focal plane 560. This results in two separate laser beam spots on focal plane 560, as illustrated in FIG. 6 discussed below. Beams 190 are optimally overlapped at a greater distance from focusing lens 160, as illustrated in FIG. 7 discussed below. In FIG. 5, the input face of optical fiber 170 is positioned at the location 562 of optimal spatial overlap between beams 190.

FIG. 6 shows an exemplary transverse profile of beam bundle 196 at focal plane 560 of focusing lens 160 in module 500. FIG. 6 also shows the input face of optical fiber 170 in a scenario where the input face of optical fiber 170 coincides with focal plane 560. Beams 190(1) and 190(2) form two distinct transverse profiles 690(1) and 690(2) at focal plane 560. Each transverse profile 690 is the 1/e² envelope of the transverse intensity distribution of the corresponding beam 190. Each transverse profile 690 has a fast-axis width similar to fast-axis width dr of the full beam bundle 196 in module 100 (see FIG. 4), but there is an offset Δ_{C} between the two transverse profiles 690. In the depicted example, the acceptance aperture D_{A} of optical fiber 170 is sufficiently large to accept beam bundle 196 of module 100 (see FIG. 4). Acceptance aperture D_{A} of optical fiber 170 is also sufficiently large to accept a single beam 190 of beam bundle 196 in module 500. However, the sizable offset Δ_{C} at focal plane 560 precludes coupling both beams 190 into optical fiber 170 at this location in module 500.

FIG. 7 shows an exemplary transverse profile 790 of beam bundle 196 at location 562 after focusing lens 160 where the spatial overlap between beams 190 is optimal. FIG. 7 also shows the input face of optical fiber 170 in the scenario where the input face of optical fiber 170 is positioned at this location of optimal spatial overlap. The transverse profile 790 at location 562 does not show two distinct beams but instead resembles the transverse profile of a single laser beam. However, because each individual beam 190 diverges from focal plane 560 to location 562, transverse profile 790 at location 562 is significantly larger than each individual transverse profile 690 at focal plane 560. A significant fraction of transverse profile 790 falls outside acceptance aperture D_{A}. This precludes coupling beam bundle 196 into optical fiber 170 without substantial loss. It may be possible to select a focusing lens 160 that focuses beams 190 tighter so as to shrink transverse profile 790 to a size that is within acceptance aperture D_{A}. However, this would likely result in a significant portion of beam bundle 196 being outside the acceptance angle θ_{A} of optical fiber 170. Furthermore, regardless of the focal length of focusing lens 160, the fast-axis beam parameter product of beam bundle 196 in module 500 is adversely affected by the uncorrected propagation-direction discrepancy between beams 190 in module 500.

The fast-axis beam parameter product of beam bundle 196 in module 500 can be evaluated at focal plane 560. The offset Δ_{C} between transverse profiles 690 in the y-dimension, at focal plane 560, is determined by offset Δ_{F} between junctions 112 (see FIG. 2) and the magnification of the imaging system formed by fast-axis lens 120 and focusing lens 160 in the yz-plane. Specifically, Δ_{C}=Δ_{F} f_{C}/f_{F}, wherein f_{C} is the focal length of focusing lens 160 in the yz-plane. The full fast-axis size d_{C} of the transverse profile of beam bundle 196 on optical fiber 170 in module 500 is approximately

$${d}_{C} = \frac{1}{2} {d}_{F} + {Δ}_{C} + \frac{1}{2} {d}_{F} = {Δ}_{C} + {d}_{F} .$$

The resulting beam parameter product in the fast-axis is approximately

$$\frac{1}{2} ( {Δ}_{C} + {d}_{F} ) {β}_{F} .$$

Thus, the fast-axis beam parameter product achievable by module 500 exceeds that achievable by module 100 by approximately

$$\frac{1}{2} {Δ}_{C} {β}_{F} .$$

It is generally impossible to avoid a substantial offset Δ_{C} between transverse profiles 690(1) and 690(2) at focal plane 560 in module 500. The low magnification f_{C}/f_{F} required to essentially eliminate offset Δ_{C} would typically cause the vast majority of the power of beams 190 to be incident on optical fiber 170 outside its acceptance angle θ_{A}. In typical practical examples, the fast-axis beam parameter product of beam bundle 196 in module 500 is at least 1.5 times as high as the corresponding beam parameter product in module 100. In certain implementations, the beam parameter product achieved in module 500 is between 2 and 10 times the beam parameter product achieved in module 100. This comparison of modules 100 and 500 illustrates how prism 140 enables coupling of beam bundle 196 into optical fiber 170 with high brightness. In module 100, beams 190 are focused and have optimal spatial overlap at the same longitudinal location.

An additional advantage of prism 140 is that section 150 can accommodate a volume Bragg grating 180 for the purpose of frequency-locking beams 190. Bragg grating 180 may be positioned in section 150 of module 100 where beams 190 are both fully collimated and parallel. In comparison, module 500 lacks a section where beams 190 are both fully collimated and parallel. Module 500 therefore does not have a location suitable for low-loss frequency locking with such a volume Bragg grating.

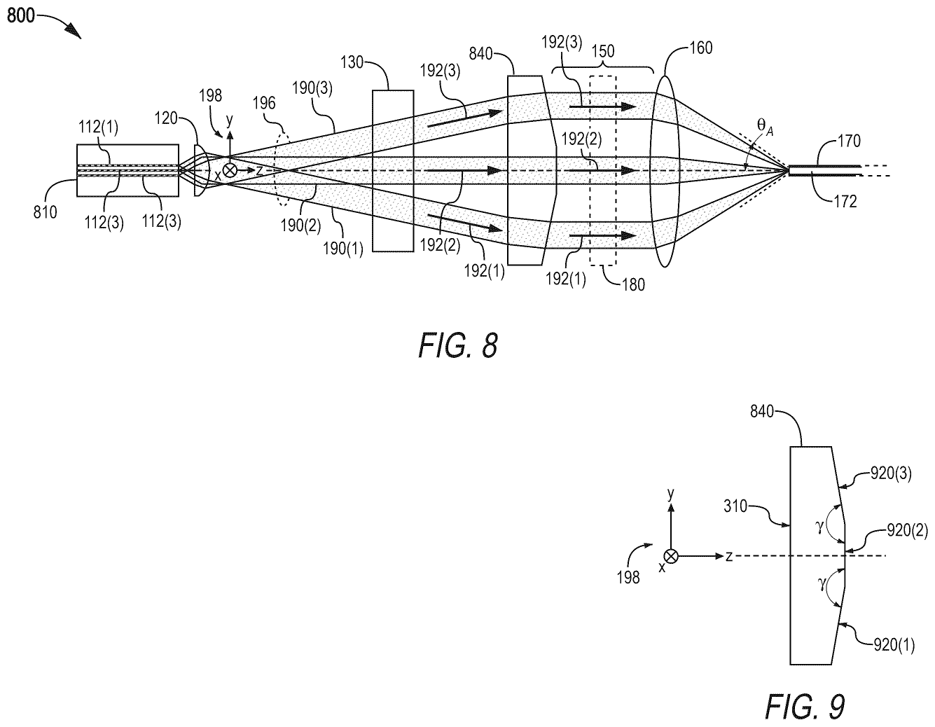

FIG. 8 illustrates one triple-junction laser-diode module 800 capable of coupling three laser beams, emitted by a triple-junction laser diode, into an optical fiber with high brightness. Module 800 is an extension of module 100 to a triple-junction laser diode emitting a bundle of three laser beams. Module 800 is similar to module 100 except that (a) dual-junction laser diode 110 is replaced by triple-junction laser diode 710 and (b) prism 140 is replaced by a prism 840 configured to correct for propagation-directions discrepancies between three different laser beams. FIG. 8 shows module 800 in a cross-sectional view similar to that used for module 100 in FIG. 1A.

Triple-junction laser diode 810 includes a stack of three junctions 112, labeled 112(1), 112(2), and 112(3) in FIG. 8. Each pair of adjacent junctions 112 are offset from each other in the vertical dimension by offset Δ_{F}. Each junction 112 emits a respective laser beam 190 having a propagation direction 192, such that the beam bundle 196 generated in module 800 includes three beams 190. After fast-axis collimation by fast-axis lens 120, the three beams 190 have three different propagation directions 192. Prism 840 corrects for this discrepancy between the three propagation directions 192 by deflecting the two outermost beams 190 of bundle 196 and transmitting the centermost beam 190 undeflected.

FIG. 9 shows prism 840 in further detail. Prism 840 is similar to prism 140 except for including three output facets 920 instead of two output facets 320. Each output facet 920 is planar and arranged at a different respective orientation relative to the xz-plane. In module 800, beam 190(1) passes through input facet 310 and output facet 920(1), beam 190(2) passes through input facet 310 and output facet 920(2), and beam 190(3) passes through input facet 310 and output facet 920(3). Output facet 920(2) is parallel to input facet 310. The interior angle γ between each pair of adjacent output facets 920 is less than 180 degrees and typically obtuse.

In the embodiment of module 100 depicted in FIGS. 1A and 2, fast-axis lens 120 and prism 140 do not deflect the central propagation axis of beam bundle 196. Similarly, in the embodiment of module 800 depicted in FIGS. 8 and 9, fast-axis lens 120 and prism 840 do not deflect the central propagation axis of beam bundle 196. Without departing from the scope hereof, prism 140/840 and/or fast-axis lens 120 may deflect the central propagation axis propagation axis of beam bundle 196 in modules 100 and 800, while retaining the advantages discussed above, particularly the benefit of the prism correcting the propagation-directions discrepancies between the incident laser beams. Deflection of the central propagation axis may take place deliberately or be the result of an unintentional alignment error, e.g., wherein fast-axis lens 120 is not optically centered on the z-axis and/or the input facet of prism 140/840 is at an oblique angle relative to the central propagation axis of the incident beam bundle 196.

Module 100 is readily extended to multi-junction laser diodes having a stack of more than three junctions 112. In such extensions, prism 140 has more than three planar, mutually nonparallel output facets. More specifically, this prism has a different output facet for each laser beam emitted by the multi-junction laser diode and the output facets of the prism are oriented such that all beams 190 emitted by the multi-junction laser diode are parallel when emerging from the prism. In embodiments with an odd number of laser junctions 112 emitting an odd number of laser beams 190, the prism may be configured to transmit a centermost laser beam 190 undeflected. More generally, for both even and odd numbers of laser beams 190, the prism is configured to deflect all or all but one of the laser beams. In embodiments where one of the laser beams passes through the prism undeflected, this undeflected laser beam may or may not be a centermost laser beam. However, it may be advantageous that the effect of the prism on the laser beam bundle is symmetric, for example as depicted in FIGS. 1A and 8 for modules 100 and 800. Nevertheless, many different prism designs are suitable, other than those depicted in FIGS. 1A, 3, 8, and 9.

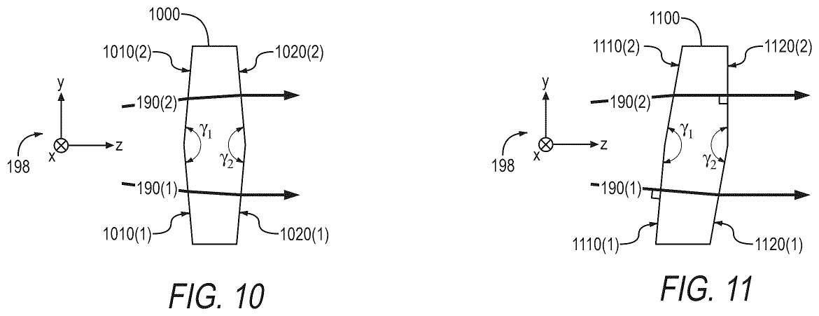

FIG. 10 illustrates one prism 1000 that may replace prism 140 in module 100. When implemented in module 100, prism 1000 deflects each beam 190 at both the input side and the output side of prism 1000. Prism 1000 includes two planar, mutually nonparallel input facets 1010(1) and 1010(2) and two planar, mutually nonparallel output facets 1020(1) and 1020(2). In module 100, beam 190(1) passes through input facet 1010(1) and output facet 1020(1), and beam 190(2) passes through input facet 1010(2) and output facet 1020(2). In FIG. 10, each beam 190 is represented by its beam axis. The interior angle γ₁ between input facets 1010(1) and 1010(2) may be the same as or different from the interior angle γ₂ between output facets 1020(1) and 1020(2). Each of interior angles γ₁ and γ₂ is obtuse.

The configuration of prism 1000, characterized by deflection of each incident laser beam 190 at both the input side and the output side of the prism, is readily extended to modifications of module 100 where beam bundle 196 includes three or more beams 190.

FIG. 11 illustrates another prism 1100 that may replace prism 140 in module 100. Prism 1100 is asymmetric. When implemented in module 100, beam 190(1) is deflected only at the output side of prism 1100, and beam 190(2) is deflected only at the input side of prism 1100. Prism 1100 includes two planar, mutually nonparallel input facets 1110(1) and 1110(2), and two planar, mutually nonparallel output facets 1120(1) and 1120(2). The interior angle 11 between input facets 1110(1) and 1110(2) is less than 180 degrees. Similarly, the interior angle 12 between output facets 1120(1) and 1120(2) is less than 180 degrees. Angles γ₁ and γ₂ are typically obtuse. Beam 190(1) passes through input facet 1110(1) and output facet 1120(1), and is deflected only at output facet 1120(1). Beam 190(2) passes through input facet 1110(2) and output facet 1120(2), and is deflected only at input facet 1110(2). The asymmetric nature of prism 1100 is readily extended to modifications of module 100 where beam bundle 196 includes three or more beams 190.

The different prisms illustrated in FIGS. 1A-11 are only examples of prisms capable of correcting the propagation-direction discrepancies between the transmitted laser beams. Furthermore, without departing from the scope hereof, in embodiments where one laser beam passes through the prism undeflected, this undeflected laser beam may bypass the prism entirely or pass through an opening in the prism. It is even possible, although more complicated in terms of alignment, to replace each of the prisms discussed above with two or more separate parts. For example, prism 840 of module 800 may be replaced by (a) one part that forms output facet 920(1) and the portion of input facet 310 intersected by beam 190(1) and (b) another part that forms output facet 920(3) and the portion of input facet 310 intersected by beam 190(3), with a gap existing between these two parts such that beam 190(2) can pass through this gap. In addition, each of the prisms discussed herein may be replaced by a transmissive, diffractive optical element that deflects the incident laser beams in the same manner as the prism. This transmissive, diffractive optical element may have zero optical power. Thus, more generally, module 100 (and, similarly, each of its extensions to more junctions 112 and beams 190) includes, in place of prism 140, a transmissive beam-deflecting element that deflects all or all but one of the incident beams 190 such that beams 190 are parallel when emerging from the transmissive beam-deflecting element. Typically, the transmissive beam-deflecting element has zero optical power.

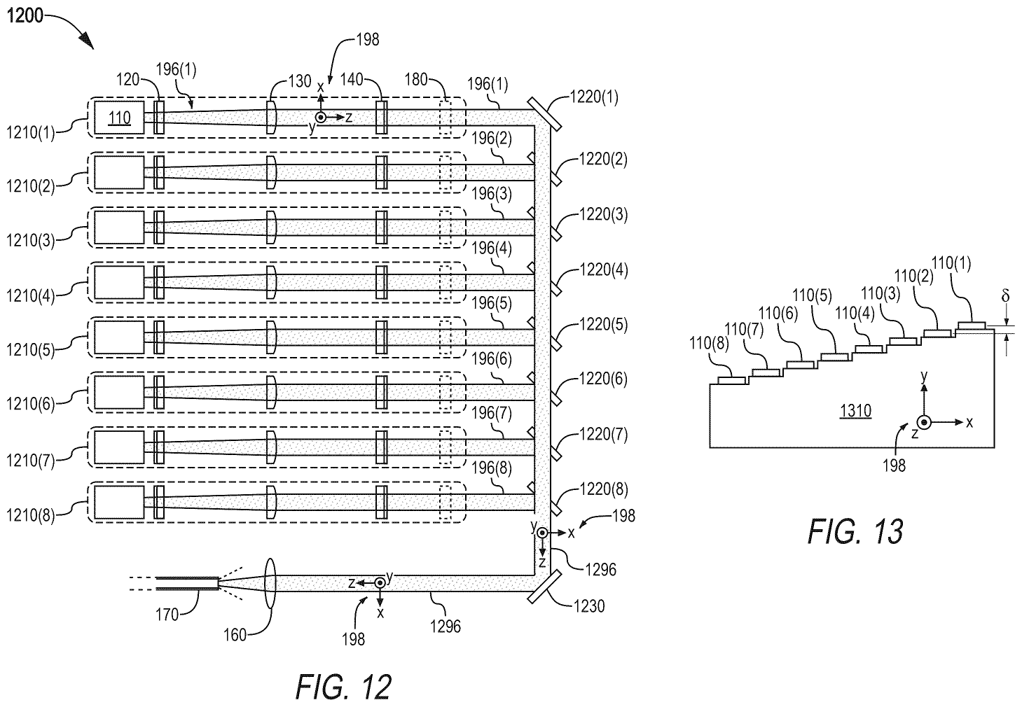

FIGS. 12 and 13 illustrate one dual-junction laser-diode apparatus 1200 that includes multiple dual-junction laser-diode modules 1210, arranged side-by-side, and combines the output thereof. Each module 1210 is an embodiment of module 100 that includes neither focusing lens 160 nor optical fiber 170. The output of each module 1210 is therefore a corresponding instance of beam bundle 196 characterized by beams 190 being collimated and mutually parallel. In the depicted embodiment, apparatus 1200 includes eight modules 1210(1-8). More generally, apparatus 1200 includes at least two modules 1210, for example between 2 and 25 modules 1210. Without loss of generality, the following discussion assumes that apparatus 1200 contains eight modules 1210. FIG. 12 is a top view of apparatus 1200. The fast axes of beams 190 emerging from diodes 110 of modules 1210 are orthogonal to the plane of FIG. 12. FIG. 13 is a front view of the output faces of diodes 110(1-8) of the respective modules 1210(1-8) of apparatus 1200.

Diodes 110 are arranged in a staircase fashion with a vertical offset δ between adjacent diodes 110, such that beam bundles 196 emerge from modules 1210 with vertical offsets δ therebetween. The propagation of beam bundles 196 is generally horizontal, that is, in the plane of FIG. 12, although individual beams 190 within each beam bundle 196 deviate from strict horizontal propagation until deflected by prism 140 (see FIG. 1A). Diodes 110 may be mounted on a staircase structure 1310.

For each module 1210, apparatus 1200 includes a corresponding mirror 1220 that deflects the corresponding beam bundle 196. Mirrors 1220 are arranged to stack beam bundles 196 on top of each other. Beam bundle 196(1) is reflected by mirror 1220(1) and passes over mirrors 1220(2-8) and over beam bundles 196(2-8), beam bundle 196(2) is reflected by mirror 1220(2) below beam bundle 196(1) and passes over mirrors 1220(3-8) and over beam bundles 196(3-8), etc. Mirrors 1220(1-8) thereby stack beam bundles 196(1-8) vertically in a super-bundle 1296.

Apparatus 1200 may further include focusing lens 160 and optical fiber 170 (or a fiber port configured to receive optical fiber 170). In apparatus 1200, focusing lens 160 couples super-bundle 1296 into optical fiber 170. Apparatus 1200 may also include one or more mirrors 1230 that change the propagation direction of super-bundle 1296 before coupling into optical fiber 170 by focusing lens 160.

Vertical offsets δ may be chosen in accordance with the following two considerations. First, it is preferable that vertical offsets δ are large enough to ensure no or only negligible obscuration loss from the lower beam 190 from each of modules 1210(1-7) as it is transmitted over mirror 1220 associated with the adjacent lower beam module 1210. Secondly, optimal coupling into optical fiber requires that vertical offsets δ are sufficiently small that all beams 190 of super-bundle 1296 are incident on optical fiber 170 within its acceptance angle.

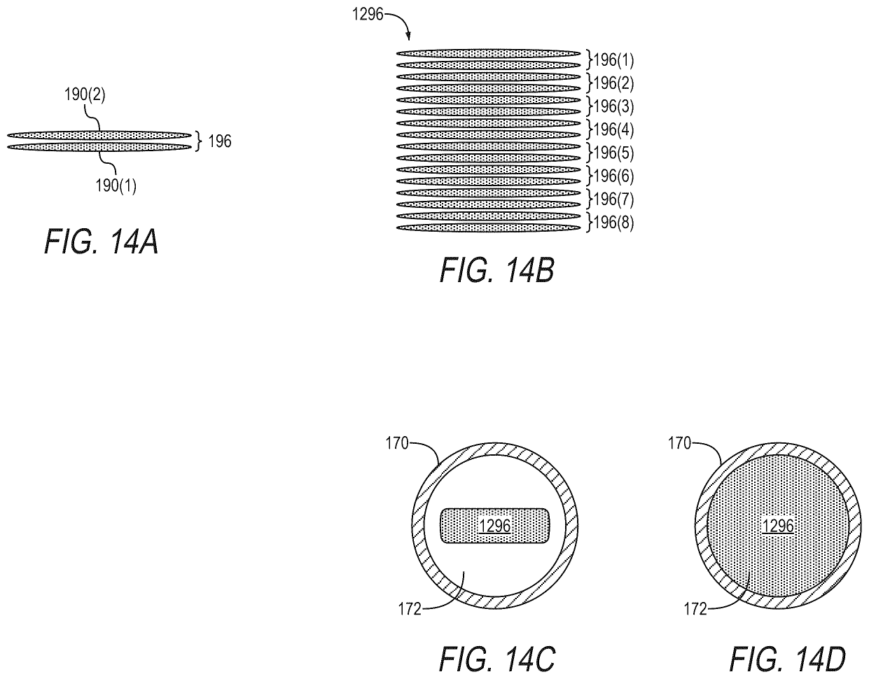

FIGS. 14A-D are a series of exemplary laser beam profiles taken at different locations in apparatus 1200. FIG. 14A is a transverse cross section of one beam bundle 196 in apparatus 1200 taken at the output of the corresponding module 1210. FIG. 14A shows the 1/e² envelope of the transverse intensity distributions of the two beams 190 of beam bundle 196. FIG. 14B is a transverse cross section of super-bundle 1296 taken before focusing lens 160. Bundles 196(1-8) are vertically stacked on each other in super-bundle 1296. In the depicted example, separation distance S_{F} (see FIG. 1A) and vertical offsets δ (see FIG. 13) are set to achieve equal spacing between all beams 190 of super bundle 1296 for the purposes of optimal coupling into, and optimal brightness out of, optical fiber 170. FIG. 14C shows the 1/e² envelope of the transverse intensity distributions of super-bundle 1296 as focused on an input face of optical fiber 170 by focusing lens 160. Because all beams 190 of super-bundle 1296 are collimated and, by virtue of prisms 140, parallel to each other before focusing lens 160, focusing lens 160 is capable of coupling super-bundle 1296 into optical fiber 170 with high brightness. FIG. 14D is a transverse cross section of super-bundle 1296 at an output face of optical fiber 170. After a certain propagation length through optical fiber 170, super-bundle 1296 is relatively uniformly distributed across the transverse dimensions of core 172 of optical fiber 170.

The design of apparatus 1200 is not limited to dual-junction laser diodes 110. One or more of modules 1210 may be replaced with multi-junction laser diodes having three or more junctions 112 and thus emitting three or more beams 190 (as discussed above for modules 100 and 800).

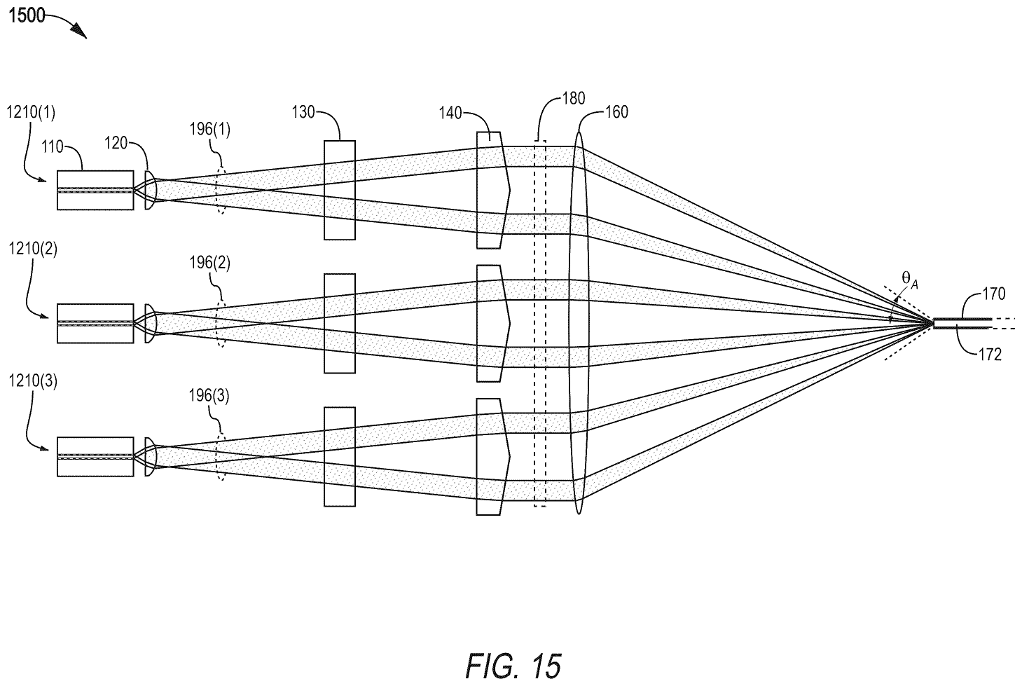

FIG. 15 illustrates another dual-junction laser-diode apparatus 1500 that includes multiple dual-junction laser-diode module 1210 and combines the output thereof. Whereas modules 1210 are arranged side-by-side in apparatus 1200, modules 1210 are stacked on each other vertically in apparatus 1500, i.e., distributed along the vertical dimension of diodes 110. All beams 190 of apparatus 1500 thereby propagate in a common plane, that is, the plane of FIG. 15. This eliminates the need for mirrors to combine beams 190. In apparatus 1500, modules 1210 may share a single, common volume Bragg grating 180 for frequency locking beams 190.

Apparatus 1500 may include focusing lens 160 and optical fiber 170 (or a fiber port configured to receive optical fiber 170). Focusing lens 160 couples beams 190 from all modules 1210 into optical fiber 170. Apparatus 1500 may be made more compact than apparatus 1200. However, apparatus 1200 may be able to accommodate more modules 1210 than apparatus 1500. In the depicted embodiment, apparatus 1500 includes three modules 1210. More generally, apparatus 1500 includes two or more modules 1210, for example between two and five modules 1210. The number of modules 1210 may be limited by the acceptance aperture and angle of optical fiber 170.

The present invention is described above in terms of a preferred embodiment and other embodiments. The invention is not limited, however, to the embodiments described and depicted herein. Rather, the invention is limited only by the claims appended hereto.

What is claimed is:

1. A multi-junction laser-diode module, comprising:
a multi-junction laser diode including a plurality of laser junctions stacked in a vertical dimension, the plurality of laser junctions being configured to emit a respective plurality of laser beams offset from each other in the vertical dimension, each laser beam diverging more rapidly in a fast axis than in an orthogonal slow axis, the fast axis of each laser beam being parallel to the vertical dimension where the laser beam emerges from the multi-junction laser diode; and
a fast-axis cylindrical lens configured to collimate each laser beam in the fast axis, whereby the laser beams emerge from the fast-axis cylindrical lens with mutually nonparallel propagation directions;
a transmissive beam-deflecting element disposed after the fast-axis cylindrical lens and configured to deflect all or all but one of the laser beams in a first plane, parallel to the fast axes of the laser beams, such that the laser beams emerge from the transmissive beam-deflecting element with mutually parallel propagation directions; and
a slow-axis cylindrical lens configured to collimate each laser beam in the slow axis.

2. The multi-junction laser-diode module of claim 1, further comprising:
an optical fiber, or a fiber port configured to receive an optical fiber; and
a focusing lens disposed after slow-axis cylindrical lens and the transmissive beam-deflecting element and before the optical fiber or fiber port, at a location where the laser beams are fully collimated and propagate parallel to each other, the focusing lens being configured to couple the laser beams into the optical fiber or fiber port.

3. The multi-junction laser-diode module of claim 1, wherein the transmissive beam-deflecting element is disposed at a location where respective 1/e² transverse intensity distributions of the laser beams are non-overlapping.

4. The multi-junction laser-diode module of claim 1, wherein the transmissive beam-deflecting element is configured to deflect at least two laser beams.

5. The multi-junction laser-diode module of claim 1, wherein the transmissive beam-deflecting element is monolithic.

6. The multi-junction laser-diode module of claim 1, wherein the transmissive beam-deflecting element is a prism.

7. The multi-junction laser-diode module of claim 6, wherein an input side or an output side of the prism includes a plurality of planar facets that are mutually nonparallel and arranged such that each of the laser beams passes through a different respective one of the planar facets.

8. The multi-junction laser-diode module of claim 7, wherein an interior angle between each pair of adjacent planar facets is less than 180 degrees.

9. The multi-junction laser-diode module of claim 7, wherein the prism is symmetric with respect to reflection in a second plane that is orthogonal to the first plane and contains a central propagation axis of the laser beams.

10. The multi-junction laser-diode module of claim 7, wherein one of the input side and the output side includes the plurality of planar facets, and wherein the other one of the input side the output side includes a single planar facet arranged such that all laser beams pass therethrough.

11. The multi-junction laser-diode module of claim 1, wherein the transmissive beam-deflecting element is a diffractive optical element.

12. The multi-junction laser-diode module of claim 1, wherein the transmissive beam-deflecting element is disposed at a location where the mutually nonparallel propagation directions diverge from each other.

13. The multi-junction laser-diode module of claim 1, wherein the fast-axis cylindrical lens has a fast-axis focal length, and a propagation distance of the laser beams from the fast-axis cylindrical lens to the transmissive beam-deflecting element is more than the fast-axis focal length.

14. The multi-junction laser-diode module of claim 1, further comprising a volume Bragg grating disposed after the transmissive beam-deflecting element and the slow-axis cylindrical lens at a location where the laser beams are fully collimated.

15. The multi-junction laser-diode module of claim 1, wherein the multi-junction laser diode is a dual-junction laser diode, whereby the plurality of laser beams includes two laser beams, and wherein the transmissive beam-deflecting element is configured to deflect each of the two laser beams.

16. The multi-junction laser-diode module of claim 15, wherein the transmissive beam-deflecting element is a prism having an input side and an output side, one of the input side and the output side of the prism having a single planar facet intersecting the two laser beams, the other one of the input side and the output side including first and second planar facets, the first and second planar facets being mutually nonparallel, the first planar facet intersecting one of the two laser beams, the second planar facet intersecting the other one of the two laser beams.

17. The multi-junction laser-diode module of claim 1, wherein the multi-junction laser diode is a triple-junction laser diode, whereby the plurality of laser beams includes three laser beams incident on the transmissive beam-deflecting element as a centermost laser beam and two outermost laser beams, and wherein the transmissive beam-deflecting element is configured to deflect the two outermost laser beams and not deflect the centermost laser beam.

18. The multi-junction laser-diode module of claim 17, wherein the transmissive beam-deflecting element is a prism having an input side and an output side, one of the input side and the output side of the prism having a single planar facet intersecting the three laser beams, and the other one of the input side and the output side including (a) a centermost planar facet intersecting the centermost laser beam and (b) two outermost planar facets respectively intersecting the two outermost laser beams, the centermost planar facet being parallel to the single planar facet.

19. A multi-junction laser-diode apparatus, comprising:
multiple instances of the multi-junction laser-diode module of claim 1 distributed along a stacking axis, wherein each laser module generates the corresponding laser beams as a beam bundle, the vertical dimension being common to all the laser modules and the laser modules being distributed along the vertical dimension, such that the laser beams of the beam bundles emerge from the laser modules as fully collimated laser beams propagating parallel to each other in a common propagation plane parallel to the vertical dimension; and
an optical fiber, or a fiber port configured to receive an optical fiber; and
a focusing lens arranged to receive the beam bundles from the laser modules and configured to couple the laser beams of each beam bundle into the optical fiber or fiber port.

20. The multi-junction laser-diode apparatus of claim 19, further comprising a volume Bragg grating disposed between the laser modules and the focusing lens and arranged to intersect all laser beams of the beam bundles.

21. A multi-junction laser-diode apparatus, comprising:
multiple instances of the multi-junction laser-diode module of claim 1, each generating the corresponding laser beams as a beam bundle;
a plurality of mirrors arranged to combine the beam bundles into a super-bundle characterized by parallel propagation and parallel fast axes of all the laser beams of the super-bundle;
an optical fiber, or a fiber port configured to receive an optical fiber; and
a focusing lens configured to couple the super-bundle into the optical fiber or fiber port.

22. The multi-junction laser-diode apparatus of claim 21, wherein each laser module further includes a volume Bragg grating disposed after the transmissive beam-deflecting element and the slow-axis cylindrical lens of the laser module at a location where the laser beams are fully collimated.
